(19) United States
(12) Patent Application Publication
(10) Pub. No.: US 2024/0290892 A1
(43) Pub. Date: Aug. 29, 2024

(54) PHOTOVOLTAIC STRINGS AND CELLS

(71) Applicant: COMMISSARIAT À L’ENERGIE ATOMIQUE ET AUX ENERGIES ALTERNATIVES, PARIS (FR)

(72) Inventor: Armand BETTINELLI, GRENOBLE CEDEX 09 (FR)

(21) Appl. No.: 18/564,943

(22) PCT Filed: May 31, 2022
(86) PCT No.: PCT/EP2022/064719

§ 371 Date: Nov. 28, 2023

(30) Foreign Application Priority Data
Jun. 4, 2021 (FR) 2105901

(51) Int. Cl. H01L 31/02; H01L 31/05

(52) U.S. Cl. CPC H01L 31/0201; H01L 31/0508

(57) ABSTRACT

A photovoltaic cell includes a distribution track extending parallel to an edge and a plurality of collection fingers, the photovoltaic cell being remarkable in that the width of the distribution track is greater than the width of each collection finger; and wherein a plurality of interconnection conductors electrically connected to the distribution track and extending between said edge and the distribution track; and wherein the photovoltaic cell includes at least one free portion of its face delimited at least in part by the distribution track, the edge and two consecutive interconnection conductors.

### TECHNICAL FIELD OF THE INVENTION

The technical field of the invention is that of partially covering electrically connected photovoltaic cells. The present invention more particularly relates to the architecture of metallisations on at least one face of a photovoltaic cell. The invention also relates to the connection of a plurality of photovoltaic cells according to the invention.

### TECHNOLOGICAL BACKGROUND OF THE INVENTION

Photovoltaic modules are made by placing a plurality of photovoltaic cells in series to form a photovoltaic string, followed by encapsulation of the string to form a photovoltaic module. The method commonly used to form photovoltaic strings is the welding or bonding of tapes or wires to the collection fingers on the front face of a first cell and to the collection fingers on the rear face of a second cell. The first and second cells are separated by a few millimetres, approximately 3 mm, so that the tape or wire can change plane and pass from the front face of the first cell to the rear face of the second cell. The spacing between both cells increases the surface area of the string thus formed and therefore that of the final module.

There is a technique for interconnecting photovoltaic cells called “shingle”, which does not use electrical tapes or wires, making it possible to respond to the increase in the active surface area of the module. The “shingle” interconnection technique is described, for example, in the paper [“Materials challenge for shingled cells interconnection”, G. Beaucarne, Energy Procedia 98, pp. 115-124, 2016]. The photovoltaic cells forming the string are superimposed over each other, with a lower cell partially covered with the adjacent upper cell, in the same way that tiles cover a roof. The interconnection between two adjacent cells is made in the coverage zone. The front face of the lower cell and the rear face of the upper cell each include a network of collection fingers connected to a wide metallised track extending along one edge. When the string is interconnected, both metallised tracks are connected electrically and mechanically by welding or by means of an electrically conductive adhesive disposed between both metallised tracks. Photovoltaic strings thus eliminate the separation between cells, providing a continuous active surface over the entire surface of the photovoltaic string.

However, interconnected shingle photovoltaic strings pose new problems. Firstly, the electrical and mechanical reliability of the photovoltaic module requires a large coverage zone between adjacent cells within the photovoltaic string. Part of each cell, having undergone the entire functionalisation method, is not lit by the sun's rays and is therefore not used. Today's methods for manufacturing photovoltaic strings require a coverage zone in the order of 1.5 mm for photovoltaic cells measuring 156 mm×156 mm, which corresponds to an unused surface area of the photovoltaic cell of about 1%. There is therefore a need to reduce the coverage zone between adjacent cells to reduce the unused surface area of each photovoltaic cell while maintaining good electrical and mechanical reliability.

A first document, published as reference FR 3 094 570, discloses a photovoltaic string comprising first and second photovoltaic cells, the front face of the first photovoltaic cell being intended to be exposed to incident radiation and the rear face of the second photovoltaic cell being interconnected to the front face of the first photovoltaic cell. The first document discloses especially that the front face of the first photovoltaic cell has a plurality of collection fingers and a conductive interconnection track extending parallel to an edge of the photovoltaic cell within 2 mm of said edge. The interconnection between both photovoltaic cells is then provided by an electrically conductive adhesive in contact with the interconnection conductive track of the first photovoltaic cell and the rear face of the second photovoltaic cell. The conductive interconnection track can be made from so-called “high-temperature” metallisations. High-temperature metallisations comprise a glass matrix and metal particles. When heat-treated at a temperature of about 800° C., the glass matrix imparts a high level of adhesion to these metallisations on the cell surface. Interconnection is then achieved by depositing an adhesive portion cross-linking at low temperature on the interconnection track on the front face of the first photovoltaic cell. A thermal cross-linking treatment of the electrically conductive adhesive at a temperature in the order of 200° C. thus makes it possible to make the thermal and mechanical connection between both photovoltaic cells.

This type of interconnection shows good mechanical reliability. However, the treatment temperature of high-temperature metallisations is not compatible with some types of photovoltaic cells, such as heterojunction photovoltaic cells. Indeed, these cells can be damaged when the temperature exceeds 250° C. for a few minutes. The interconnection conductive track can therefore be produced using a “low temperature” metallisation ink. Said ink especially comprises a resin and metal particles. The adhesion of these low-temperature metallisations, which do not contain glass, is not as high as that of high-temperature metallisations, reducing reliability of the interconnection between the cells. On the other hand, heat treatment at a temperature in the order of 200° C. is sufficient to make thermal and mechanical connection of the first interconnection track to the face of the first photovoltaic cell. However, reliability is also reduced by the electrically conductive adhesive, comprising for example epoxy or acrylate, exhibiting poor adhesion to low temperature metallisations.

A second document, published as reference WO 2020/109408, discloses a photovoltaic cell for improving the interconnection between said cell and an interconnecting metal tape when made with a low temperature adhesive. The cell disclosed comprises metallisations forming a plurality of closed conductive contours surrounding a portion of the substrate. In order to make the interconnection, the low temperature adhesive is deposited onto each closed conductive contour so as to adhere both to the metallisations and to the substrate. The low-temperature adhesive has a higher adhesion to the substrate than to the metallisations. In this way, closed contours provide a metallised zone to provide a good electrical connection and provide a portion of the substrate for improving adhesion compared to depositing only on a metallised zone. On the other hand, the surface area of the substrate in contact with the adhesive in relation to the amount of adhesive used remains small and does not make it possible to significantly improve mechanical robustness of the interconnection while maintaining a good electrical contact quality.

There is therefore a need to further improve the interconnection between shingled interconnected photovoltaic cells, especially when the interconnection implements a low temperature adhesive.

### SUMMARY OF THE INVENTION

The invention offers a solution to the problems discussed above, by making it possible to significantly increase the amount of adhesive participating in the mechanical connection between two photovoltaic cells. The invention also makes it possible to increase the level of adhesion of the adhesive to at least one of the photovoltaic cells. In this way the robustness of the interconnection is improved.

For this, the invention relates to a photovoltaic cell comprising a first face, said first face comprising:
a first edge;
a first distribution track extending parallel to the first edge and within 5 mm of the first edge, preferably within 4 mm and even more preferably within 3 mm;
a plurality of collection fingers extending parallel to each other, said collection fingers being electrically connected to the first distribution track.

The photovoltaic cell is remarkable in that:
the width of the first distribution track is strictly greater than the width of each collection finger; and in that
the first face also comprises:
   a plurality of first interconnection conductors, said first interconnection conductors being electrically connected to the first distribution track and extending perpendicular to the first edge between said first edge and the first distribution track, the first interconnection conductors being spaced apart two by two; and
   at least one first central free portion of the first face at least partly delimited by the first distribution track, the first edge and two consecutive first interconnection conductors.

By the term “collection finger”, it is meant a conductive track for collecting electric currents produced by the photovoltaic cell.

By the term “distribution track”, it is meant a conductive track configured to perform concentration of electric currents collected by the collection fingers and to distribute these electric currents to the first interconnection conductors.

The arrangement of the first distribution track and of the collection fingers

makes it possible, on the one hand, to collect and concentrate the electrical currents produced in the vicinity of the first edge. The distribution track also makes it possible to distribute the electrical currents collected between the first interconnection conductors. In this way, the photovoltaic cell ensures good electrical interconnection when it is interconnected within a photovoltaic string.

On the other hand, the arrangement of the first distribution track and the first interconnection conductors on the first face also makes it possible to delimit a portion of the first face devoid of metallisation, so that an adhesive portion can be deposited thereon. This adhesive portion does not adhere to any metallisation and therefore offers optimum adhesion for a given amount of adhesive.

Further to the characteristics just discussed in the preceding paragraphs, the photovoltaic cell according to the invention may have one or more complementary characteristics from among the following, considered individually or according to any technically possible combinations:
the collection fingers extend parallel to the first edge and the collection fingers are electrically connected to the first distribution track by means of connection elements in the form of wires or tapes extending perpendicular to the first edge, each connection element preferably being disposed as an extension of each first interconnection conductor;
the width of each first central free portion is greater than the pitch separating the collection fingers;
the width of the first distribution track is greater than or equal to twice the width of each collection finger;
the width of each first interconnection conductor is greater than or equal to the width of the first distribution track;
the first interconnection conductors each comprise an interconnection pattern;
the first face comprises a second distribution track extending parallel to the first edge between the first distribution track and the collection fingers, the second distribution track being electrically connected to the first distribution track and preferably by means of a plurality of bonding conductors each extending perpendicular to the first edge, the width of the second distribution track being greater than the width of each collection finger and preferably equal to the width of the first distribution track;
the photovoltaic cell comprises a second face opposite to the first face, said second face comprising a second edge, opposite to the first edge; a third distribution track extending parallel to the second edge; a plurality of second first interconnection conductors being electrically connected to the third distribution track and extending perpendicular to the second edge between said second edge and the third distribution track, the second interconnection conductors being spaced apart two by two; and at least one second central free portion partly delimited by the third distribution track, the second edge and two consecutive second interconnection conductors;
the width of each second central free portion is equal to the width of each first central free portion;
each second central free portion is opposite to a first central free portion; and
the photovoltaic cell comprises a semiconductor stack, said semiconductor stack being preferably with heterojunction.

The invention also relates to a method for manufacturing a photovoltaic cell according to the invention, comprising the following steps of:
forming on a first face of a substrate, a first distribution track extending parallel to a first edge and within 5 mm of the first edge and a plurality of collection fingers extending parallel to each other, said collection fingers being electrically connected to the first distribution track, the width of the first distribution track being strictly greater than the width of each collection finger; and
forming on the first face of the substrate a plurality of first interconnection conductors, said first interconnection conductors being electrically connected to the first distribution track and extending perpendicular to the first edge between said first edge and the first distribution track, the first interconnection conductors being spaced apart two by two and-at least one first central free portion of the first face being at least partly delimited by the first distribution track, the first edge and two consecutive first interconnection conductors.

Another aspect of the invention relates to a photovoltaic string comprising:
a first photovoltaic cell according to the invention;
a second photovoltaic cell; and
at least one first adhesive portion.

Said second photovoltaic cell is bonded to the first photovoltaic cell by means of each first adhesive portion, one face of the second photovoltaic cell partially covering the first face of the first photovoltaic cell, each first adhesive portion adhering to a first central free portion of the first face of the first photovoltaic cell and to the face of the second photovoltaic cell.

Further to the characteristics just discussed in the preceding paragraphs, the photovoltaic string according to the invention may have one or more additional characteristics from among the following, considered individually or according to any technically possible combinations:
each first adhesive portion is distant from each first interconnection conductor of the first face of the first photovoltaic cell;
each first adhesive portion is distant by at least 1 mm from each first interconnection conductor of the first face of the first photovoltaic cell;
a plurality of first adhesive portions adhere to the first central free portion of the first face of the first photovoltaic cell and to the face of the second photovoltaic cell;
the sum of the lengths of each first adhesive portion is less than the width of the first central free portion;
the face of the second photovoltaic cell comprises an edge in vertical alignment with the first face of the first photovoltaic cell, each first adhesive portion being distant from the first edge of the first face of the first photovoltaic cell and from the edge of the face of the second photovoltaic cell;
each first adhesive portion is distant by at least 0.05 mm from the first edge of the first face of the first photovoltaic cell and from the edge of the face of the second photovoltaic cell;
the face of the second photovoltaic cell covers the first edge and partially overlaps the first face of the first photovoltaic cell over a coverage distance from the first edge, the width of each first adhesive portion being less than the coverage length;
the photovoltaic string comprises a plurality of second portions of electrically conductive adhesive, each second adhesive portion electrically connecting a first interconnection conductor of the first face of the first photovoltaic cell to the face of the second photovoltaic cell;
he length of each first adhesive portion is greater than the length of each second adhesive portion;
the width of each first adhesive portion is greater than the width of each second adhesive portion; and
the face of the second photovoltaic cell comprises a plurality of discrete electrodes spaced apart from each first interconnection conductor of the first face of the first photovoltaic cell,
each second adhesive portion connecting a first interconnection conductor to a discrete electrode.

Finally, a last aspect of the invention relates to a method for manufacturing a photovoltaic string comprising the following steps of:
providing a first photovoltaic cell according to the invention, a second photovoltaic cell and-at least one first adhesive portion;
depositing each first adhesive portion onto a first central free portion of the first face of the first photovoltaic cell; and
bonding the second photovoltaic cell to the first photovoltaic cell by means of each first adhesive portion, one face of the second photovoltaic cell partially covering the first face of the first photovoltaic cell, each first adhesive portion adhering to a first central free portion of the first face of the first photovoltaic cell and to the face of the second photovoltaic cell.

The invention and its different applications will be better understood upon reading the following description and upon examining the accompanying figures.

### BRIEF DESCRIPTION OF THE FIGURES

The figures are set forth by way of indicating and in no way limiting purposes of the invention.

FIG. 1, FIG. 2, FIG. 3, FIG. 4, FIG. 5, FIG. 6, schematically represent first, second, third, fourth, fifth, sixth embodiments of a photovoltaic cell according to the invention.

FIG. 7 represents schematically an implementation mode of a method for manufacturing a photovoltaic cell according to the invention.

FIG. 8, FIG. 9, FIG. 10, FIG. 11, FIG. 12, FIG. 13, schematically represent first, second, third, fourth, fifth, sixth embodiments of a photovoltaic string according to the invention.

FIG. 14 represents schematically an implementation mode of a method for manufacturing a photovoltaic string according to the invention.

The figures are set forth by way of indicating and in no way limiting purposes the invention. Unless otherwise specified, a same element appearing in different figures has a single reference.

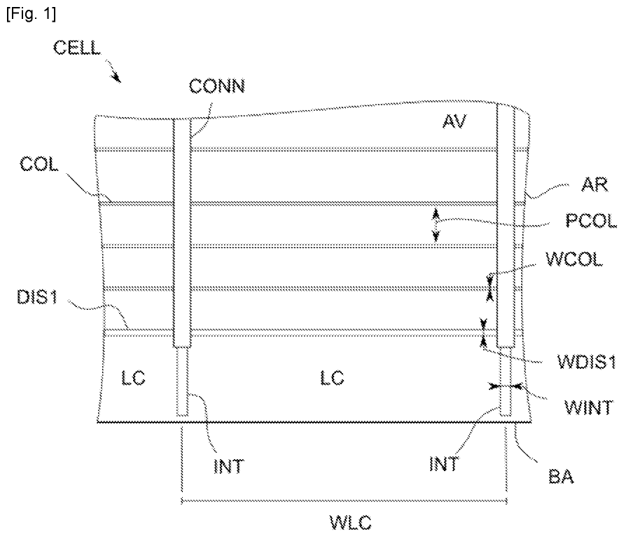

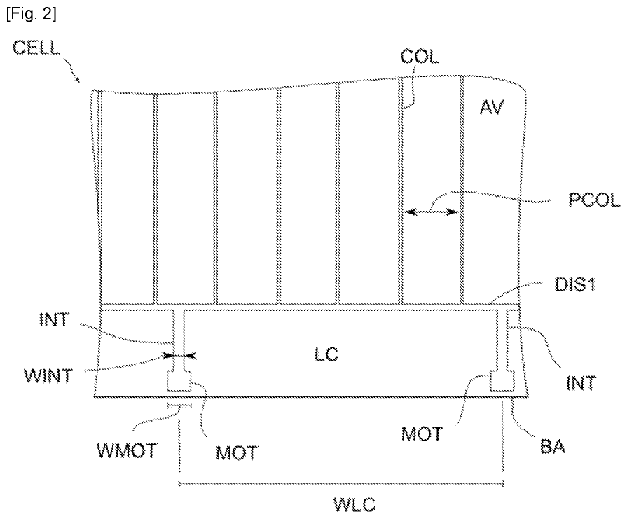

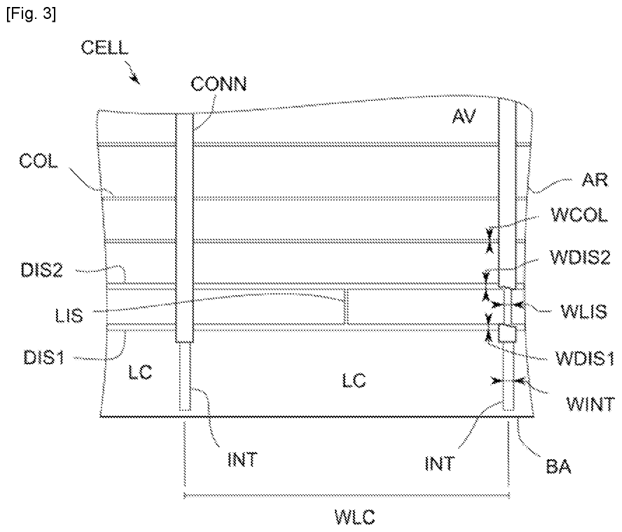

### DETAILED DESCRIPTION

[FIG. 1] to [FIG. 6] illustrate different embodiments of a photovoltaic cell CELL according to the invention. The photovoltaic cell CELL, which may also simply be referred to as a cell CELL, provides means of improving interconnection with another photovoltaic cell in a “shingle” type photovoltaic string. By “shingle”, it is meant a stack of cells partially covering in the same way as roof tiles cover each other, with a zone of the rear face of an upper cell being electrically and mechanically connected to a zone on the front face of a lower cell. The cell CELL according to the invention especially makes it possible to improve robustness of the mechanical bonding with at least one other cell in a photovoltaic string.

The cell CELL according to the invention offers a particular advantage when it comprises metallisations made from a so-called “low-temperature” paste and when the mechanical interconnection between the cells is made by means of a so-called “low-temperature” adhesive. The low-temperature paste and the low-temperature adhesive comprise, for example, an epoxy-or acrylate-based resin.

For this, the cell CELL is advantageously manufactured from a homojunction or heterojunction semiconductor stack. In the latter case, the semiconductor stack may advantageously comprise a layer of transparent conductive oxide for collecting part of the electrical currents generated by the finished cell CELL. This transparent conductive oxide layer also offers good adhesion with epoxy-or acrylate-based resins that can be found in a low-temperature adhesive. Indeed, resins of this type adhere two to three times better to a conductive transparent oxide surface than to a metallised surface made from a low temperature paste.

In common with the embodiments illustrated by [FIG. 1] to [FIG. 5], the cell CELL comprises a first face AV advantageously extending over a surface of the semiconductor stack. The cell CELL also advantageously comprises a second face AR, extending over another surface of the semiconductor stack and opposite to the first face AV. Advantageously, the first face AV constitutes a front face of the cell, that is a face for receiving light radiation. Of course, the first and second faces AV, AR may be interchanged, with the second face AR being able to be the face for receiving light radiation.

The first face AV is advantageously rectangular or pseudo-rectangular and comprises at least one first edge BA. The first edge BA is advantageously the edge covered with an upper cell when the cell CELL is interconnected in a shingle-type photovoltaic string. The upper cell then covers a zone on the first face AV referred to as the “coverage zone”. The mechanical and electrical interconnection of the cells in the photovoltaic string is moreover advantageously carried out in the coverage zone. The coverage zone thus extends parallel to the first edge BA to within one coverage length of the first edge BA. In order to reduce shading caused by the upper cell, the coverage length is advantageously small, that is less than or equal to 2 mm, or even less than or equal to 1.5 mm. The improvement in mechanical interconnection made possible by the cell CELL according to the invention makes it possible especially to contemplate an even shorter coverage length, for example equal to 0.5 mm.

Said first face AV comprises metallisations, also called “conductive tracks” or “discrete electrodes” and described below, the arrangement of which is configured to ensure collection and conveying of the electrical currents generated by the cell CELL. The arrangement of said metallisations makes it possible especially to ensure a robust mechanical connection between the cells of a string and low resistive losses. However, the arrangement can also be configured to minimise amount of paste used to make the metallisations. Indeed, metallisations described below can be made by screen printing using a low-temperature paste containing, for example, a resin loaded with silver particles. The cost of manufacturing a cell then depends in part on the amount of low-temperature paste used. A judicious arrangement of the metallisations therefore makes it possible to optimise the amount of paste used and thus reduce the manufacturing cost of a cell CELL.

Thus, the first face AV comprises a first distribution track DIS1, one of the functions of which is to centralise currents collected by means of collection fingers COL (described below) and to distribute them to first interconnection conductors INT (also described below). In this respect, the first distribution track is not a collection finger. However, it can contribute to the collection of electrical current in the vicinity of the coverage zone. The first distribution track DIS1 additionally extends parallel to the first edge BA. The first distribution track DIS1 extends over a substantial distance from the first face AV, for example more than 75% of the length of the first edge BA, or even more than the length of the first edge BA itself, especially when the first face AV has a pseudo-rectangular shape. In which case, the length of the first interconnection track DIS1, extending from one side edge to the other of the first face AV, may be greater than the length of said first edge BA. The first distribution track DIS1 may be made by screen-printing a low-temperature paste as previously described.

The first distribution track DIS1 extends within 5 mm of the first edge BA. Preferably, the first track DIS1 extends to within 4 mm, or even within 3 mm. Thus, when the cell CELL is interconnected in a photovoltaic string, the first distribution track DIS1 can be positioned in the vicinity of the coverage zone. In this way, the length required of the first interconnection conductors INT to reach the coverage zone can be reduced, especially reducing the amount of conductive ink implemented.

The first face AV also comprises a plurality of collection fingers COL ensuring collection of electric currents generated by the cell CELL. For this purpose, the collection fingers COL extend parallel to one another and preferably occupy most of the first face AV. To enable electrical currents to be conveyed when the cell CELL is interconnected within a string, the collection fingers COL are electrically connected to the first distribution track DIS1. In this way, the electrical currents collected can be distributed to the first interconnection conductors INT by means of the first distribution track DIS1. The collection fingers COL can also be made by screen-printing a low-temperature paste.

The first distribution track DIS1 is responsible for concentrating electric currents collected by the collection fingers COL and redistributing them to the first interconnection conductors INT. For this, the cell CELL is remarkable in that the width WDIS1 of the first distribution track DIS1 is strictly greater than the width WCOL of each collection finger COL. In this way, the first distribution track DIS1 allows a greater current density to be transported than each collection finger COL. The width WCOL of each collection finger COL is advantageously measured perpendicular to the direction along which they extend. The width WDIS1 of the first distribution track DIS1 is advantageously measured perpendicular to the first edge BA. The collection fingers COL may have a width WCOL of between 30 μm and 50 μm. The first distribution track DIS1 may then have a width WDIS1 of between 60 μm and 100 μm.

The cell CELL is also remarkable in that the first face AV also comprises a plurality of first interconnection conductors INT. The first interconnection conductors INT can advantageously convey electrical currents collected towards the coverage zone when the cell CELL is interconnected in a string. They thus make it possible to ensure a reliable electrical interconnection with a higher cell when necessary. For this, said first interconnection conductors INT extend perpendicular to the first edge BA between said first edge BA and the first distribution track DIS1. Each first interconnection conductor INT may moreover have an end disposed within 2 mm from the first edge BA, or even disposed within 0.5 mm of the first edge BA, or even disposed on the first edge BA. The further the first interconnection conductors INT extend in the direction of the first edge BA, the easier it is to connect them electrically with an upper cell during interconnection within a string. Said first interconnection conductors INT are additionally electrically connected to the first distribution track DIS1 so that electrical currents can be conveyed.

The first interconnection conductors INT are spaced apart two by two. By virtue of this, at least one first central free portion LC of the first face AV is at least partly delimited by the first distribution track DIS1, the first edge BA and two consecutive first interconnection conductors INT. Each first central free portion LC is therefore devoid of metallisation. As a reminder, resins or polymers making up so-called “low-temperature” adhesives show poor adhesion to metallisations made from a low-temperature paste. So, when the cell CELL is interconnected in a photovoltaic string, all of the adhesive that is deposited onto a first central free portion LC adheres to said first central free portion LC with a high level of adhesion. Adhesion is also advantageously improved when the cell CELL comprises a heterojunction semiconductor stack especially comprising a conductive transparent oxide surface. Indeed, low-temperature adhesives show an adhesion two to three times higher on a conductive transparent oxide surface than on a surface metallised with a low-temperature paste.

Each first central free portion LC extending between the first edge BA and the first dispensing track DIS1, extends at least partly into the coverage zone when the cell CELL is interconnected. Thus, each first central free portion LC can receive an adhesive portion and participate in the interconnection of the cells within a photovoltaic string.

By “at least partly delimited”, it is meant that the perimeter of each first central free portion LC comprises at least one portion of the first distribution track DIS1, at least one portion of the first edge BA and two consecutive first interconnection conductors INT. In other words, each first central free portion LC is disposed between the first distribution track DIS1 and the first edge BA and between two consecutive first interconnection conductors INT.

In order to benefit from a large surface area in the coverage zone for each first central free portion LC, it is preferable for the first distribution track DIS1 to be disposed on the surface of the cell CELL in such a way that it is located outside the coverage zone when the cell CELL is interconnected.

In a manner common to the embodiments illustrated by [FIG. 1], [FIG. 3], [FIG. 4] and [FIG. 5], the collection fingers COL may extend parallel to the first edge

BA and therefore parallel to the first distribution track DIS1. In this case, the electrical connection between collection fingers COL and the first distribution track DIS1 can advantageously be made by means of connection elements CONN. The connection elements CONN are in the form of wires or tapes and extend perpendicular to the collection fingers COL and to the first distribution track DIS1. Each connection element CONN is advantageously connected to each collection finger COL, for example by means of a weld located at the intersection between the connection element CONN and a collection finger COL. The connection elements CONN are also offset to the first distribution track DIS1, to which they can also be connected by means of a localised weld. In this way, electrical currents collected by the collection fingers COL can be conveyed to the first distribution track DIS1. The connection elements CONN advantageously extend over the first face AV, outside a zone to be covered by an upper cell during interconnection, that is more than the coverage length of the first edge BA. Indeed, in order to reduce resistive losses, the CONN interconnection elements may have a thickness which may adversely affect mechanical robustness of the interconnection when they are disposed in the coverage zone. In addition, limiting length of the CONN interconnection elements reduces consumption of raw materials implemented in the manufacture of photovoltaic cells, such as copper or silver.

Each connection element CONN is advantageously disposed as an extension of each electrical interconnection conductor INT. In this way, the path travelled by electrical currents from the collection fingers COL to the interconnection conductors INT is small. Each connection element CONN is advantageously aligned with an interconnection conductor INT.

According to one embodiment illustrated by [FIG. 2], the collection fingers COL may extend perpendicular to the first edge BA. In this way, it is not necessary to resort to connection elements. Indeed, the collection fingers COL are extended up to the first distribution track DIS1 so as to be connected directly to said first distribution track DIS1. The manufacturing steps are simplified as it is no longer necessary to align and weld the connection elements. On the other hand, this makes it necessary to have COL collection conductors with low resistivity and therefore requires the implementation of a larger amount of low-temperature paste for making metallisation of the cell CELL.

In common with the embodiments illustrated by [FIG. 1] to [FIG. 4], the width WLC of each first central free portion LC is advantageously greater than the pitch PCOL separating the collection fingers COL. The pitch PCOL is advantageously measured between two consecutive collection fingers COL, perpendicularly to the direction along which the collection fingers COL extend. The width WLC of each first central free portion LC is advantageously measured parallel to the first edge BA. It corresponds especially to the deviation between the first interconnection conductors INT, the latter being spaced apart two by two. Thus, the greater the width WLC of each first central free portion LC, the more adhesive can be applied to the first central free portion LC during interconnection. The mechanical connection with an upper cell is further improved by the larger the dimensions of the adhesive portions.

In order to provide large central free portions LC, the width WLC of each first central free portion LC is advantageously greater than 3 mm and preferably greater than 4.5 mm. The width WLC of each first central free portion LC may for example be equal to 6 mm or 8 mm.

The greater the width WLC of each first central free portion LC, that is the greater the deviation between the first interconnection conductors INT, the smaller the number of first interconnection conductors INT relative to the number of collection fingers COL. In order to reduce resistive losses due to the smaller number of first interconnection conductors INT, it is advantageous to dimension the width WINT of each interconnection conductor INT so that it can allow lossless circulation of currents collected by the collection fingers COL.

The widths WDIS1, WINT of the first distribution track DIS1 and of each first interconnection conductor INT advantageously depend on the number of first interconnection conductors INT. When the number of collection fingers COL is much greater than the number of first interconnection conductors INT, there is a high concentration of electric currents in the first distribution track DIS1. In addition, electric currents concentrated in the first distribution track DIS1 circulate over greater distances. The first distribution track DIS1 and the first interconnection conductors INT therefore preferably have widths WDIS1, WINT that are strictly greater than the width WCOL of each collection finger COL. The widths WDIS1, WINT of the first distribution track DIS1 and of the first interconnection conductors INT can advantageously depend on a ratio between the number of collection fingers COL and the number of first interconnection conductors INT. The higher this ratio (in favour of the collection fingers), the greater said widths WIDS1, WINT. The widths WDIS1, WINT of the first distribution track DIS1 and of the first interconnection conductors INT may also depend on the thicknesses of the conductors. Indeed, the collection fingers COL, which are thinner, may have a small thickness of slightly less than ten micrometres. On the other hand, the first distribution track DIS1 and the first interconnection conductors INT, which are wider, may have a greater thickness than the collection fingers COL.

Thus, the first distribution track DIS1 advantageously has a width WDIS1 greater than or equal to twice the width WCOL of each collection finger COL. For example, for a width WCOL of collection fingers COL of between 30 μm and 50 μm, for example 40 μm, the first distribution track DIS1 advantageously has a width WDIS1 of between 60 μm and 100 μm, for example approximately 80 μm.

In the same way, the width WINT of each first interconnection conductor INT is advantageously greater than or equal to the width WDIS1 of the distribution track DIS1. For example, for a width WDIS1 of the first distribution track DIS1 of between 60 μm and 100 μm, for example 80 μm, each first interconnection conductor INT has a width WINT of between 80 μm and 120 μm, for example 100 μm.

In a manner common to the embodiments illustrated by [FIG. 2] and [FIG. 4], each first interconnection conductor INT comprises an interconnection pattern MOT. The interconnection patterns MOT increase the conductive surface area of each first interconnection conductor INT enabling, for example, improved electrical conduction when the cell CELL is interconnected in a string. For this, the interconnection patterns MOT are preferentially disposed on each first interconnection conductor INT, in proximity to the first edge BA, for example within 1 mm of the first edge BA.

The interconnection patterns MOT may be solid, as illustrated in [FIG. 2]. Therefore, they provide a larger electrical conduction zone and reduce the resistivity between the interconnected cells. The interconnection patterns MOT may also comprise a closed contour surrounding a portion of the first face AV, as illustrated in [FIG. 4]. They provide a larger conduction zone compared to first interconnection conductors INT that do not include a pattern. They also, by virtue of the closed contour, retain flow of an uncured adhesive portion, thereby reducing the occurrence of shading due to adhesive drips onto the faces AV, AR of the cell CELL. The width WMOT of the interconnection patterns MOT, measured parallel to the first edge BA is greater than the width WINT of the first interconnection conductors INT and preferably greater than twice the width WINT of the first interconnection conductors INT. For example, when a first interconnection conductor INT has a width WINT of 100 μm, the associated pattern MOT may have a width WMOT of 200 μm.

In common with the embodiments of [FIG. 3] and [FIG. 4], the first face AV comprises a second distribution track DIS2 instead of one and a single first track DIS1 as illustrated in [FIG. 1], [FIG. 2] and [FIG. 5]. The first and second distribution tracks DIS1, DIS2 extend in parallel to the first edge BA. The second distribution track DIS2 preferentially extends between the collection fingers COL and the first distribution track DIS1. In the same way as the first distribution track DIS1, the second distribution track DIS2 extends over a substantial distance from the front face BA, for example more than 75% of the length of the first edge BA. Both distribution tracks DIS1, DIS2 are also preferably spaced apart by a distance equal to the pitch PCOL separating the collection fingers COL.

One of the functions of the second distribution track DIS2 is also to perform concentration of the electrical currents collected so that they can be transmitted to the first interconnection conductors INT. Thus, the collection fingers COL are preferentially at least electrically connected to the second distribution track DIS2, the latter being positioned closer to said collection fingers than the first track DIS1. The collection fingers COL can also be electrically connected by means of connection elements CONN, extending perpendicular to the first edge BA and connecting therebetween the collection fingers COL and the second distribution track DIS2. The first interconnection conductors INT are preferably electrically connected to the first distribution track DIS1, the latter being closer to the first edge BA than the second track DIS2.

In order that the collected electrical currents can circulate from the collection fingers COL to the first interconnection conductors INT, the first and second distribution tracks DIS1, DIS2 are electrically connected to each other. Electrical connection between both tracks DIS1, DIS2 can be made by means of connection elements CONN thereby extending from the first distribution track DIS1 to the collection fingers COL, connecting the second distribution track DIS2. However, in order to limit the technical complexity of aligning and connecting connection elements CONN, it may be preferable to make the electrical connection between both distribution tracks by means of a plurality of bonding conductors LIS, as illustrated in [FIG. 3] and [FIG. 4]. The bonding conductors LIS extend, for example, perpendicular to the first edge BA. Moreover, in order to reduce the path travelled by electric currents in the distribution tracks DIS1, DIS2 and thus reduce resistive losses, bonding conductors LIS may be disposed as an extension of the first interconnection conductors INT.

It is advantageous for the connection elements CONN to extend at least partly over the bonding conductors LIS, as illustrated in [FIG. 3]. In this way, the path travelled by electrical currents collected up to the first interconnection conductors INT is reduced. The connection elements CONN can then extend over part of a bonding conductor LIS or over the entire bonding conductor LIS up to the first distribution track DIS1.

The bonding conductors LIS may have a width WLIS, measured parallel to the first edge BA, of between 40 μm and 120 μm. The bonding conductors LIS as an extension of the first interconnection conductors INT advantageously have a width WLIS of between 60 μm and 120 μm. The bonding conductors LIS distant from the first interconnection conductors INT advantageously have a width WLIS of between 40 μm and 60 μm.

For the same reasons as the first distribution track DIS1, the second distribution track DIS2 has a width WDIS2, measured perpendicularly to the first edge BA, which is strictly greater than the width WCOL of each collection finger COL. Preferably, the widths WDIS1, WDIS2 of the first and second distribution tracks DIS1, DIS2s are preferentially equal.

Whether the first face AV comprises one or two distribution tracks DIS1, DIS2, the central free portions remain delimited by the first distribution track DIS1, the first edge BA and two consecutive first interconnection conductors INT.

Advantageously, the cell CELL comprises a second face AR, opposite to the first face AV. The first face AV may correspond to a front face of the cell CELL, likely to be exposed to solar radiation so that the cell CELL can supply electric energy. According to another example, the second face AR may correspond to a front face and be directly exposed to solar radiation or correspond to a rear face and be exposed to solar radiation by reflection of the radiation from a surface having a high albedo.

According to this latter example, the second face AR can also have metallisations allowing the radiation to reach the surface of the cell CELL and collect electric currents generated. The second face AR then advantageously comprises metallisations of the same nature as the first face AV, especially for improving the mechanical connection of said cell CELL when the latter is interconnected in a string.

For this end, the second face AR, one embodiment of which is illustrated in [FIG. 6], advantageously comprises a second edge BR, opposite to the first edge BA. For the sake of clarity and unless otherwise stated, the thickness of the cell CELL, measured perpendicular to the first and second faces AV, AR, is neglected in the description and associated figures. Also the edges of the first face AV are the same as the edges of the second face AR.

Advantageously, the second face AR comprises a third distribution track DISR extending parallel to the second edge BR.

The second face AR also advantageously comprises a plurality of second interconnection conductors INTR being electrically connected to the third distribution track DISR. Each second interconnection conductor INTR extends perpendicular to the second edge BR, between said second edge BR and the third distribution track DISR. In the same way as the first distribution track DIS1, the third distribution track DISR ensures concentration of electrical currents collected on the second face AR by collection fingers and distributes said currents to the second interconnection conductors INTR. For this, the width of the third conductive track DISR is advantageously equal to the width WDIS1 of the first distribution track DIS1.

The third distribution track DISR, the second edge BR and two consecutive second interconnection conductors INTR thus make it possible to delimit at least one second central free portion LCR of the second face AR. Each second central free portion LCR is thus devoid of metallisations, in the same way as each first central free portion LC, making it possible to offer improved adhesion with a low-temperature adhesive when the cell CELL is interconnected in a string

The second interconnection conductors INTR are also advantageously spaced apart two by two. The distance between the second interconnection conductors INTR two by two is preferentially greater than the pitch separating collection fingers extending over the second face AR. Said distance separating the collection fingers may for example be 0.7 mm, in which case the distance between the second INTR interconnection conductors two by two is advantageously greater than 0.7 mm, for example equal to 3 mm. In order to facilitate interconnection between two cells CELL according to the invention, it is advantageous for the distance separating the second interconnection conductors INTR two by two to be identical to the distance separating the first interconnection conductors INT two by two. In this way, the width of each second central free portion LCR, measured parallel to the second edge BR, is equal to the width WLC of each first central free portion LCR, measured parallel to the first edge BA. In this way, the connection of the first face of a first cell CELL according to the invention and of the second face of a second cell CELL according to this example enables maximum advantage to be taken of the first and second central free portions LC, LCR. The adhesion of an adhesive portion to a central free portion will not be limited by the dimension of the other central free portion. Furthermore, it is advantageous that each second interconnection conductor INTR is aligned with a first interconnection conductor INT. In this way, the first and second central free portions LC, LCR are aligned and opposite to each other. Thus, it is possible to position two cells CELL according to the invention partially covering each other so that their first and second central free portions LC, LCR are facing each other.

According to one embodiment illustrated by [FIG. 5], the first face AV comprises a side edge BL extending from the first edge BA. The side edge BL may be straight or curved. In the first case, when the side edge BL is straight, it may form a rectangular cell edge. In the second case, when the side edge BL is curved, it can form a pseudo-rectangular cell edge referred to as a “pseudo-square”. This is especially the case illustrated in [FIG. 5]. In this case, the side edge BL describes an arc of a circle starting from the first edge BA. The side edge BL may correspond to an edge of an ingot from which the photovoltaic cell is cut. A side free portion LL may be partly delimited by the first distribution track DIS1, the first edge BA and the side edge BL and a first interconnection conductor INT consecutive to the side edge BL. The free side portion LL can thus accommodate an adhesive portion in order to contribute to the mechanical connection with an upper cell in a photovoltaic string. The free side portion LL thus has a width WLL, measured parallel to the first edge BA, equal to the distance between the first interconnection conductor INT consecutive to the side edge BL and said side edge BL. The distance is measured from the end of the first consecutive edge BA of the side edge BL and the first interconnection conductor INT.

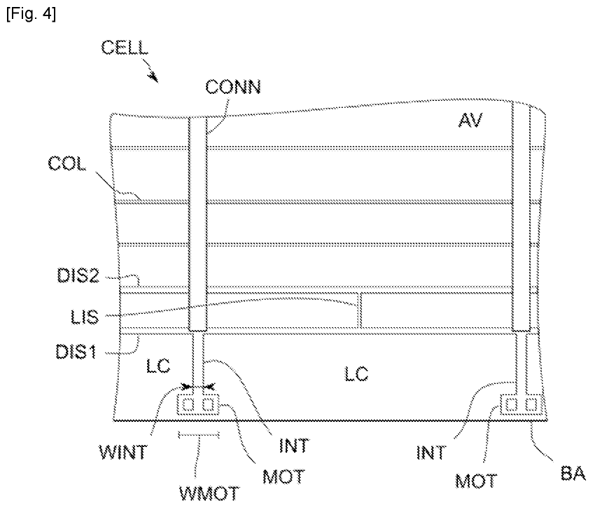

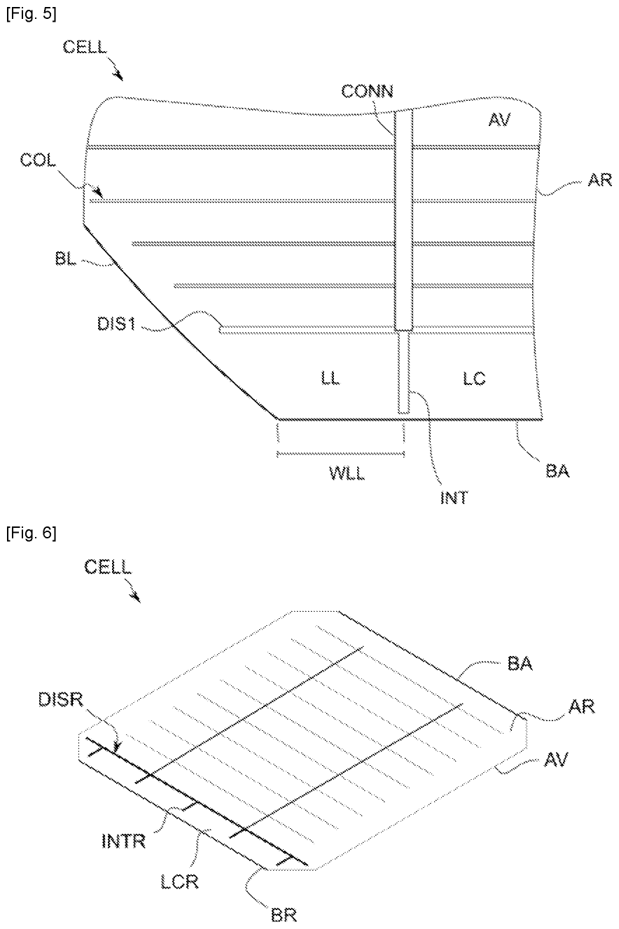

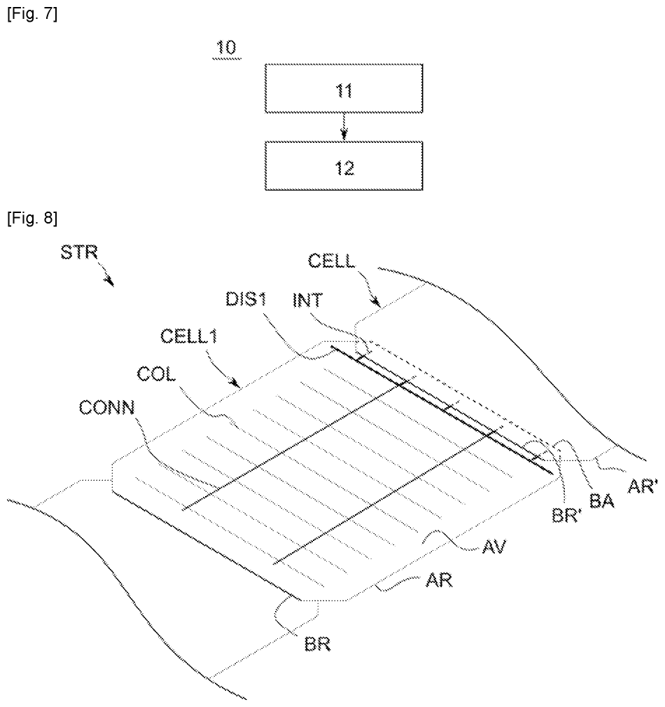

FIG. 7 illustrates an implementation mode of a method for manufacturing a method for manufacturing 10 a cell according to the invention. Manufacturing 10 the cell comprises a first step 11 of forming on a first face of a substrate:
a first distribution track extending parallel to a first edge and within 5 mm of the first edge; and
a plurality of collection fingers extending parallel to one another, said collection fingers being electrically connected to the first distribution track, the width of the first distribution track being strictly greater than the width of each collection finger.

The first distribution track and the collection fingers may be screen printed using a paste comprising a resin and metal particles.

Manufacturing 10 the cell also comprises a second step 12 of forming on the first face of the substrate:
a plurality of first interconnection conductors, said first interconnection conductors being electrically connected to the first distribution track and extending perpendicular to the first edge between said first edge and the first distribution track, the first interconnection conductors being spaced apart two by two; and
at least one first central free portion of the first face being at least partly delimited by the first distribution track, the first edge and two consecutive first interconnection conductors.

The first interconnection conductors may also be screen printed using a paste comprising a resin and metallic particles.

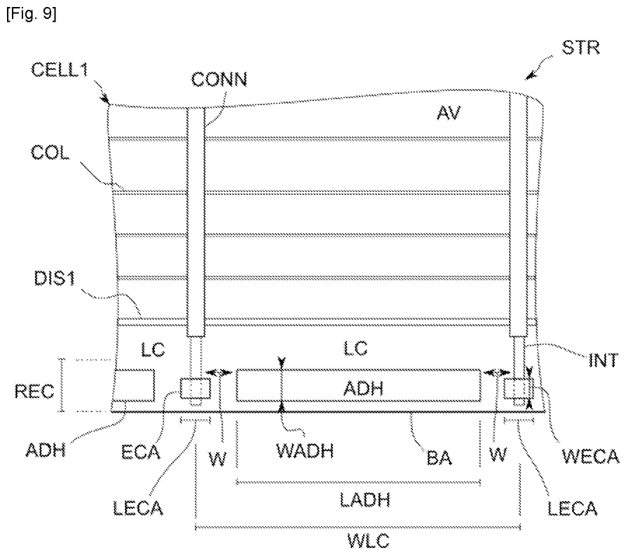

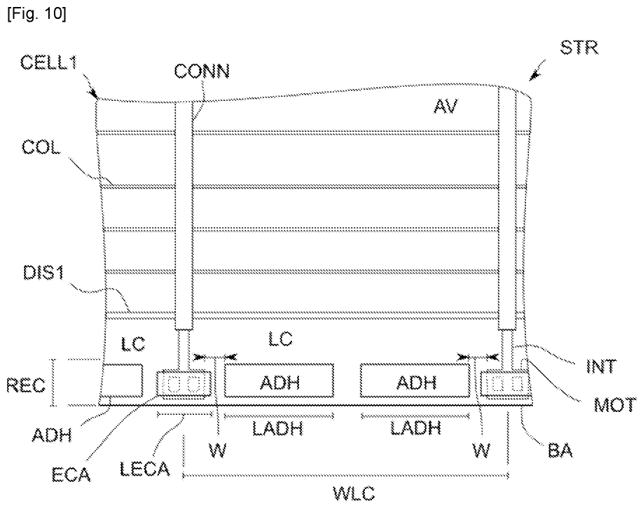

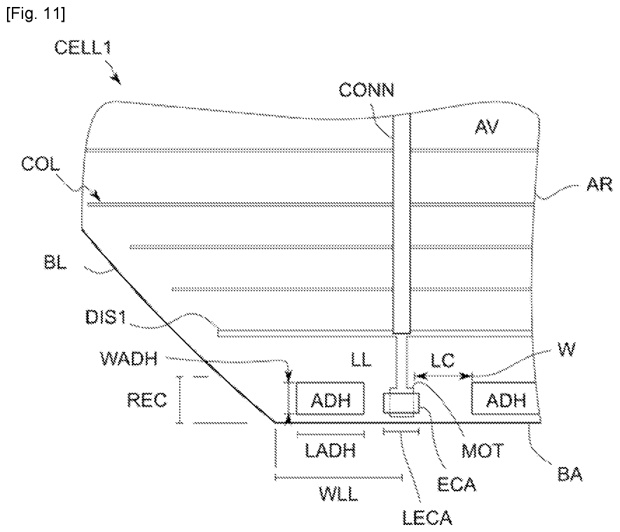

The first and second formation steps 11, 12 are advantageously carried out simultaneously.

[FIG. 8] to [FIG. 13] illustrate different embodiments of a photovoltaic string STR according to the invention. The photovoltaic string 30, which will also be referred to simply as the string STR, is an assembly of photovoltaic cells interconnected two by two so as to create an electrical and mechanical bonding.

The string STR is of the “shingle” type, that is the cells partially cover each other two by two, a zone on the rear face of an upper cell being electrically and mechanically connected to a zone on the front face of a lower cell. The robustness of the string STR is especially improved by virtue of the implementation of a cell according to the invention.

For this, in common with the embodiments of [FIG. 8] to [FIG. 13], the string STR is remarkable in that it comprises:
a first photovoltaic cell CELL1 according to the invention as previously described;
a second photovoltaic cell CELL2, which may be a cell according to the invention or a cell according to prior art; and
at least one first adhesive portion ADH.

The first and second cells CELL1, CELL2 are interconnected in a shingled manner, one face AR′ of the second cell CELL2 partially covering the first face AV of the first photovoltaic cell CELL1. The second cell CELL2 is therefore the upper cell of the shingle and the first cell CELL1 is therefore the lower cell of the shingle. The dotted lines in [FIG. 8] and [FIG. 12] represent elements hidden by the second cell CELL2.

The second cell CELL2 is bonded to the first cell CELL1 by means of each first adhesive portion ADH. Each first adhesive portion ADH adheres to a first central free portion LC of the first face AV of the first photovoltaic cell CELL1 and to the face AR′ of the second photovoltaic cell CELL2.

By the term “bonded”, it is meant that the first and second cells are rigidly mechanically connected.

In order to minimise shading of one cell by the other, the second cell CELL2 covers the first cell CELL1, preferably covering the first edge BA of the first face AV of the first cell CELL1. The second cell CELL2 then covers a zone on the first face AV referred to as the “coverage zone”. The coverage zone therefore extends over the first face AV from the first edge BA to a coverage length REC from the first edge BA. The mechanical and electrical interconnection of the cells CELL1, CELL2 is additionally advantageously carried out in the coverage zone, that is less than the coverage length REC of the first edge BA.

The face AR′ of the second cell CELL2 comprises an edge BR′ located vertically aligned with the first cell CELL1 when both cells CELL1, CELL2 are interconnected. The coverage zone thereby extends between the first edge BA of the first face AV of the first cell CELL1 and the edge BR′ of the face AR′ of the second cell CELL2. The edge BR′ of the face AR′ of the second cell CELL2 preferably extends parallel to the first edge BA of the first face AV of the first cell CELL1.

Shading of the second cell CELL2 on the first cell CELL1 is all the less as the coverage length REC is small. Additionally, the coverage length REC is less than 2 mm, or even less than 1.5 mm. On the other hand, it may be more difficult to manufacture a robust string with a coverage length REC of less than 1 mm. Indeed, the coverage length of a shingle-type string is mainly limited by the robustness of the mechanical connection between the cells. Strings can be subjected to significant mechanical stresses, for example during manufacture, which tends to bend them. Forces applied to the string are therefore transferred to the interconnections between the cells, where the mechanical bonding is weakest. The improvement in robustness of the mechanical bonding provided by the cell CELL1 according to the invention makes it possible to reduce the coverage length REC, for example to less than 1 mm, or even less than or equal to 0.5 mm, while ensuring good mechanical reliability of the string STR.

In order to reduce shading as much as possible and therefore the coverage length REC, each first adhesive portion ADH is advantageously disposed on a first central free portion LC of the first face AV, to within the coverage length REC of the first edge BA. In this way, the amount of adhesive implemented is limited and plays an integral part in the mechanical connection. The level of mechanical connection largely depends on the dimensions of each first adhesive portion ADH implemented and in particular their length LADH, measured parallel to the first edge BA, and their width WADH, measured perpendicular to the first edge BA. When each first adhesive portion ADH adheres to the entire region of each central free portion LC extending to within the coverage length REC of the first edge BA, then the resistance of the connection between the cells is maximum. In other words, each first adhesive portion ADH can extend at most over the width WLC of a first central free portion LC. In the same way, each first adhesive portion ADH may extend at most over the entire coverage length REC.

However, it may be advantageous to reduce the length and/or width of the first adhesive portions in order to reduce the amount of adhesive implemented. It is also advantageous that each first adhesive portion ADH is in contact only with the surface of the first cell CELL1 and not with metallised surfaces. It is therefore preferable for the length LADH of each first adhesive portion ADH to be strictly less than the width WLC of the first free portion over which it extends.

In addition, the first face AV of the first cell CELL1 may also comprise a plurality of second adhesive portions ECA for making electrical connection between the first interconnection conductors INT and the second cell CELL2. It is therefore advantageous to further reduce the length of the first adhesive portions ADH to enable the second adhesive portions ECA to be positioned. This approach is additionally preferred when the first adhesive portions ADH are electrically non-conductive. It is thereby advantageous that the first and second adhesive portions ADH, ECA do not mix so as not to reduce electrical conductivity between the first and second cells CELL1, CELL2.

Preferably, each first adhesive portion ADH is spaced apart from each first interconnection conductor INT. In this way, the amount of adhesive implemented for each first adhesive portion ADH is then integrally in contact with a free metallisation surface. Adhesion is therefore optimal. In addition, the space between the first adhesive portion ADH and each first interconnection conductor INT makes it possible to retain creep of the portion ADH when the second cell CELL2 is pressed against said portion ADH.

The distance W between each first adhesive portion ADH and each first

interconnection conductor INT is advantageously measured parallel to the first edge BA, as illustrated in [FIG. 9] and [FIG. 10].

Each first adhesive portion ADH is advantageously distant by at least 0.5 mm from each first interconnection conductor INT. Thus, the second adhesive portions ECA can be positioned on each first interconnection conductor INT without being in contact with a first adhesive portion ADH. For example, for a width WLC of first central free portion LC of 4.5 mm, the length LADH of each first adhesive portion ADH is then advantageously less than or equal to 3.5 mm. For a width WLC of the first central free portion LC of 8 mm, the length LADH of each first adhesive portion ADH is thereby advantageously less than or equal to 7 mm.

It may be advantageous to increase distance between each first adhesive portion ADH and each first interconnection conductor INT in order to improve positioning margins of the first and second adhesive portions ADH, ECA. Each first adhesive portion ADH may be distant by at least 2 mm from each first interconnection conductor INT. In this way, for a width WLC of first central free portion LC of 8 mm, the length LADH of each first adhesive portion ADH is thereby advantageously less than or equal to 4 mm.

When the first cell CELL1 has a dimension of 156 mm by 26 mm, it may comprise, for example, respectively 19 and 17 first central free portions LC of 8 mm along the longest edge, according to whether it is rectangular or pseudo-rectangular. The string STR may exhibit improved reliability by virtue of a first adhesive portion ADH having a length LADH of 4 mm on each first central free portion LC.

When the first cell CELL1 has a dimension of 156 mm by 26 mm, it may comprise, for example, 51 and 45 first central free portions LC respectively of 3 mm along the longer edge, according to whether it is rectangular or pseudo-rectangular. The string STR may exhibit improved reliability by virtue of a first adhesive portion ADH having a length LADH of 1 mm on each first central free portion LC.

To further reduce the amount of adhesive implemented, it is also advantageous to reduce the width WADH of each first adhesive portion ADH. The width WADH of each first adhesive portion ADH is advantageously less than the coverage length REC. In this way, adhesion is optimum. However, a flow of non-crosslinked adhesive may extend outside the coverage zone, for example onto the exposed surface of the first cell CELL1. When the adhesive is transparent, there is little impact on the yield of the string STR. By contrast, when the adhesive is opaque, the drop in efficiency of the string STR can be substantial. When the adhesive is electrically conductive, it can bring about short-circuit one of both cells CELL1, CELL2.

It is therefore advantageous for each first adhesive portion ADH to be spaced from each edge of the first and second cells CELL1, CELL2. As each first adhesive portion ADH is disposed at the coverage zone, it is thereby advantageous for each first adhesive portion ADH to be spaced apart from the first edge BA of the first photovoltaic cell CELL1 and from the edge BR′ of the second photovoltaic cell CELL2. Thus, each first adhesive portion ADH is disposed in the coverage zone and has a gap with the edges BA, BR′ of the first and second cells CELL1, CELL2 for retaining a flow of adhesive.

It is advantageous that the distance between each first adhesive portion ADH and each edge BA, BR′ depends on the tolerances achievable by screen printing. Screen-printing equipment offers an adhesive dot positioning tolerance in the order of 0.05 mm. It is therefore advantageous for each first adhesive portion ADH to be at least 0.05 mm from each edge BA, BR′ of the first and second cells CELL1, CELL2.

Thus, for a coverage length REC of 0.5 mm, each first adhesive portion ADH may have a width WADH less than or equal to 0.4 mm, for example equal to 0.35 mm. In the latter case, the positioning tolerance between the first edge BA of the first cell CELL1 and the edge BR′ of the second cell CELL2 is 0.075 mm on either side of each first adhesive portion ADH.

Thus, by virtue of the invention, the coverage length REC and the shading associated therewith can be greatly reduced while providing a robust mechanical connection of the string STR.

Advantageously, the string STR, illustrated in [FIG. 10], comprises a plurality of first adhesive portions ADH adhered to a first central free portion LC. Thus, and for the reasons set forth above, the length LADH of each first adhesive portion ADH disposed on a first central free portion LC is preferably chosen so that each first adhesive portion ADH is distant from each first interconnection conductor INT.

The adhesive used to form each first portion ADH preferably comprises an epoxy or acrylate based resin. On the other hand, it is not necessary for this adhesive to comprise metallic particles in order to make it conductive. Indeed, the first adhesive portions ADH do not participate in electrical conduction, so it is advantageous, especially in terms of manufacturing cost and saving raw materials, for each first adhesive portion ADH to be electrically non-conductive, that is electrically insulating. However, in order to simplify manufacturing steps of the string STR, it may also be contemplated to use the same adhesive to make the mechanical and electrical connection (described below). In which case, the adhesive may be electrically conductive and each first adhesive portion ADH may then be electrically conductive.

In common with the embodiments illustrated in [FIG. 9] to [FIG. 13], the string STR comprises a plurality of second adhesive portions ECA, each second adhesive portion ECA adheres to a zone of each first interconnection conductor INT of the first face AV of the first cell CELL1. Each second adhesive portion ECA also adheres to the face AR′ of the second cell CELL2. The second adhesive portions ECA participate in the electrical interconnection of the string STR and are therefore electrically conductive. For example, they can be made using an electrically conductive adhesive, comprising for example a resin loaded with metal particles, such as silver particles.

The second adhesive portions ECA are advantageously positioned in the coverage zone, that is within the coverage length REC of the first edge BA. In this way, all of the electrically conductive adhesive implemented to form the second adhesive portions ECA participates in the electrical interconnection of the string STR. In order to reduce resistive losses in the coverage zone, it is advantageous for the second adhesive portions ECA to extend over interconnection patterns MOT, as illustrated in [FIG. 10] and [FIG. 11]. Indeed the interconnection patterns MOT provide a larger metallised surface area for improving the electrical connection.

As the second adhesive portions ECA play little or no part in the mechanical connection with the second cell CELL2, it is not necessary for them to have a large surface area. Each second adhesive portion ECA advantageously covers the width WINT of a first interconnection conductor INT and preferably the width WMOT of an interconnection pattern MOT. For this, each second adhesive portion ECA can have a length LECA of between 0.9 mm and 2 mm. Thus, the length

LECA of each second adhesive portion ECA, measured parallel to the first edge BA, is advantageously less than the length LADH of each first adhesive portion ADH. In this way, the amount of electrically conductive adhesive implemented is reduced.

In order to limit the risk of mixture between the first and second adhesives ADH, ECA, each first adhesive portion ADH is distant from each second adhesive portion ECA. Thus, each first and second adhesive portion ADH, ECA is separated by a safety space providing a positioning tolerance and making it possible to retain any adhesive flow. It is advantageous to dimension the length LADH of each first adhesive portion ADH according to the length LECA of each second adhesive portion ECA and vice versa. For example, each first adhesive portion ADH is distant by at least 0.1 mm from each second adhesive portion ECA. In the example illustrated in [FIG. 10], the first cell CELL1 may comprise a first central free portion LC having a width of 8 mm, first interconnection conductors INT comprising interconnection patterns MOT having a width of 0.5 mm. Said cell CELL1 may advantageously comprise second adhesive portions ECA having a length LECA of 0.9 mm and a first adhesive portion ADH having a length LADH of 6 mm.

In order to further reduce the amount of raw material implemented during the interconnection of the string STR, the width WECA of each second adhesive portion ECA, illustrated in [FIG. 9], may advantageously be less than the width WADH of each first adhesive portion ADH. Advantageously, it depends on the coverage length REC. When the coverage length REC is equal to 0.5 mm, the width WECA of each second adhesive portion ECA can be between 0.15 mm and 0.3 mm.

On the other hand, in order to reduce resistive losses at the interconnection, it is advantageous for each second adhesive portion ECA to extend over most of each first interconnection conductor INT positioned in the coverage zone. However, in order to avoid a flow of electrically conductive adhesive out of the coverage zone, it is advantageous for each second adhesive portion ECA to be distant from the edges of each cell CELL1, CELL2, for example by at least 0.05 mm and preferably by at least 0.1 mm. Thus, when the coverage length REC is equal to 0.5 mm, the width WECA of each second adhesive portion ECA is advantageously between 0.15 mm and 0.4 mm, advantageously between 0.15 mm and 0.3 mm. For example, the width WADH of a first adhesive portion ADH may be equal to 0.350 mm and the width WECA of a second adhesive portion ECA may be equal to 0.250 mm.

The second cell CELL2 may be a cell according to prior art or according to the invention. For example, when the second cell CELL2 is a cell according to prior art, it may comprise metallisations on the face AR′ covering the first cell CELL1. This may be a full-plate metallisation covering the entire face AR′ or a discrete electrode placed in the coverage zone. These metallisations ensure electrical continuity when the first and second CELL1, cell CELL2s are interconnected. However, in order to improve robustness of the mechanical connection between both cells, it is advantageous for the second cell CELL2 to be able to offer a free portion of its face AR′ enabling the level of adhesion of the first portions of adhesive ADH with said face AR′ to be increased. Thus, the second cell CELL2 can advantageously be a cell according to the invention offering a central free portion. The face AR′ of the second cell CELL2 may correspond to its rear face, so it is particularly advantageous for the second cell CELL2 to comprise metallisations as described in [FIG. 6]. Thus. the second cell CELL2 then comprises at least one second central free portion LCR to be contacted with a first adhesive portion ADH disposed on a first central free portion LC of the first cell CELL1.

However, without necessarily being a cell according to the invention, the second cell CELL2 may comprise a plurality of discrete electrodes ED extending preferentially perpendicular to the first edge BA of the first cell CELL1. When the second cell CELL2 is a cell according to the invention, it may thereby be the second interconnection conductors INTR extending over the face AR′. When the second cell CELL2 is a cell according to prior art, it may be conductive tracks, such as collection fingers, extending over the face AR′ and at least partly into the coverage zone. In order to provide robust adhesion, the discrete electrodes ED are advantageously spaced apart two by two by a distance equal to the width WLC of the first central free portion LC of the first cell CELL1. In this way, no metallisation significantly reduces the surface area free of any metallisation of the first central free portion LC, and therefore no metallisation reduces the level of adhesion of each first adhesive portion ADH to the face AR′ of the second cell CELL2. The discrete electrodes ED can be aligned with the first interconnection conductors INT, so that the dimensions of the second adhesive portions ECA can be reduced, the distance between an interconnection conductor INT and the electrode ED associated therewith being reduced. By the term “aligned”, it is meant that each discrete electrode ED can be superimposed with a first interconnection conductor INT when the tiles are superimposed.

However, the alignment of the discrete electrodes ED with the first interconnection conductors INT tends to increase the space Z between the first face AV of the first cell CELL1 and the face AR′ of the second cell CELL2. Indeed, the discrete electrodes ED and the first interconnection conductors INT have a thickness of between 10 μm and 20 μm. The space Z between both faces AV, AR′, measured perpendicularly to said faces, can thereby be between 20 μm and 40 μm. The greater the spacing Z between the faces AV, AR′, the greater the amount of adhesive to be implemented to produce each first adhesive portion ADH. In order to reduce the amount of adhesive implemented, the discrete electrodes ED are advantageously misaligned with respect to each first interconnection conductor INT as illustrated in [FIG. 13]. By the term “misaligned”, it is meant that each discrete electrode ED is not superimposed on a first interconnection conductor INT. In other words, each discrete electrode ED is spaced from each first interconnection conductor INT. The pitch between the first interconnection conductors INT may be equal to the pitch between the discrete electrodes ED, by contrast the discrete electrodes ED are preferably translated parallel to the first edge BA by a distance of between 50 μm and 300 μm. Each discrete electrode ED is thus at least 50 μm to 300 μm from a first interconnection conductor INT. In this way, the discrete electrodes ED do not face the first interconnection conductors INT and the space Z between the faces AV, AR′ can be reduced. The amount of adhesive required to form the first adhesive portions ADH can thereby be reduced, for example by half. On the other hand, the length LECA of each second adhesive portion ECA is advantageously increased to enable a first interconnection conductor INT to be connected to a discrete electrode ED. The length of each second adhesive portion ECA may, for example, be between 500 μm and 1500 μm.

FIG. 11 illustrates one embodiment of the string STR comprising a first cell CELL1 having a pseudo-rectangle type shape. That is to say, the first face AV comprises a side edge BL starting from the first edge BA. The first face AV illustrated in [FIG. 11] especially comprises a side free portion LL, described in more detail in [FIG. 5]. In order to enhance mechanical connection between the first and second cells CELL1, CELL2, a first adhesive portion ADH is advantageously disposed at the side free portion LL, adhering to the side free portion LL and to the face AR′ of the second photovoltaic cell CELL2. For the same reasons as previously set out, the first adhesive portion ADH implemented is preferably electrically non-conductive.

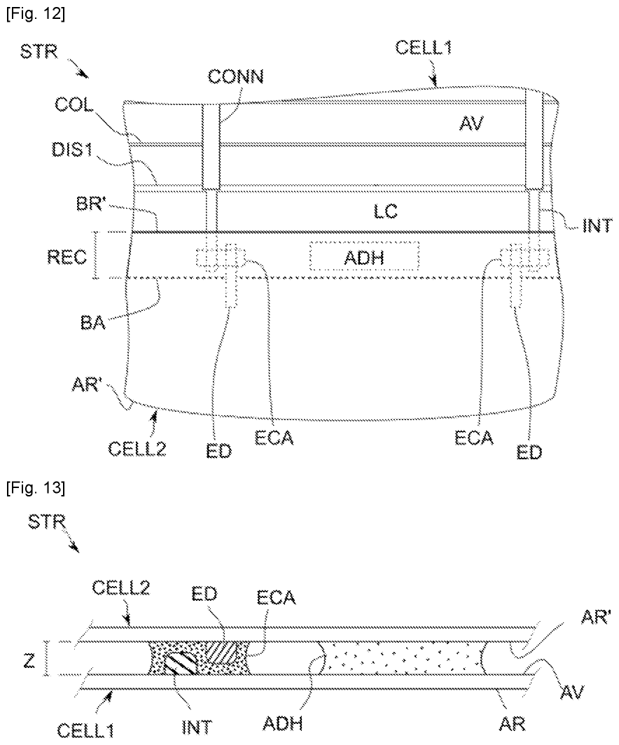

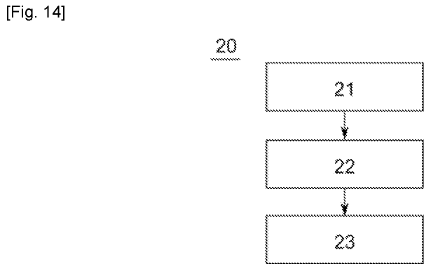

The first adhesive portion ADH deposited at the side free portion LL is advantageously distant from the first interconnection conductor INT consecutive to the side edge BL and is also advantageously distant from the side edge BL. The length LADH of the first adhesive portion ADH is in this case less than the width WLL of the side free portion LL. In order to simplify making the first adhesive portions ADH, each adhesive portion advantageously has the same width WADH, regardless of whether it is deposited at a first central free portion LC or at the side free portion LL.

[FIG. 14] illustrates an implementation mode of a method for manufacturing 20 a string according to the invention.

Manufacturing 20 the string comprises firstly providing 21 a first cell according to the invention, a second cell and-at least one first adhesive portion.

Next, manufacturing 20 the string then comprises depositing 22 each first adhesive portion onto a first central free portion of the first face of the first photovoltaic cell. Each first adhesive portion may be screen-printed from an epoxy- or acrylate-based resin. In order to facilitate implementation of deposition 22, the adhesive implemented advantageously has a rheology enabling it to be screen-printed in a well-defined pattern with limited widening with respect to the open pattern in the screen-printing screen, for example having a widening of less than or equal to 50 μm.

One alternative implementation to deposition 22 comprises depositing the first and second adhesive portions simultaneously. When the first adhesive portions are non-conductive, it may be difficult to screen print them simultaneously. For this, the first adhesive portions can be deposited onto the first face of the first cell while the second portions of electrically conductive adhesive are deposited onto the second face of the second cell. This requires the second cell to be turned upside down between both depositions and the use of a grooved screen printing table to avoid contact of a first adhesive portion with a second adhesive portion. A further alternative implementation comprises depositing the adhesives without contact, for example by ink jet depositing each first adhesive portion.

Finally, manufacturing 20 the string comprises bonding 23 the second cell to the first cell by means of each first adhesive portion, a face of the second cell partially covering the first face of the first cell, each first adhesive portion adhering to a central first free portion of the first face of the first cell and to the face of the second cell.

1. A photovoltaic cell comprising a first face, said first face comprising:
a first edge;
a first distribution track extending parallel to the first edge and within 5 mm of the first edge; and
a plurality of collection fingers extending parallel to each other, said collection fingers being electrically connected to the first distribution track;
wherein:
a width of the first distribution track is strictly greater than a width of each collection finger; and
the first face also comprises:
a plurality of first interconnection conductors, said first interconnection conductors being electrically connected to the first distribution track and extending perpendicular to the first edge between said first edge and the first distribution track), the first interconnection conductors being spaced apart two by two; and
at least one first central free portion of the first face at least partly delimited by the first distribution track, the first edge and two consecutive first interconnection conductors.

2. The photovoltaic cell according to claim 1, wherein the collection fingers extend parallel to the first edge and wherein the collection fingers are electrically connected to the first distribution track by connection elements in the form of wires or tapes extending perpendicular to the first edge.

3. The photovoltaic cell according to claim 1, wherein a width of each first central free portion is greater than a pitch separating the collection fingers.

4. The photovoltaic cell according to claim 1, wherein the width of the first distribution track is greater than or equal to twice the width of each collection finger.

5. The photovoltaic cell according to claim 1, wherein a width of each first interconnection conductor is greater than or equal to the width of the first distribution track.

6. The photovoltaic cell according to claim 1, wherein the first interconnection conductors each comprise an interconnection pattern.

7. The photovoltaic cell according to claim 1, wherein the first face comprises a second distribution track extending parallel to the first edge between the first distribution track and the collection fingers, the second distribution track being electrically connected to the first distribution track, the width of the second distribution track being greater than the width of each collection finger.

8. The photovoltaic cell according to claim 1, comprising a second face opposite to the first face, said second face comprising:
a second edge, opposite to the first edge;
a third distribution track extending parallel to the second edge;
a plurality of second first interconnection conductors being electrically connected to the third distribution track and extending perpendicular to the second edge between said second edge and the third distribution track, the second interconnection conductors being spaced apart two by two; and
at least one second central free portion partly delimited by the third distribution track, the second edge and two consecutive second interconnection conductors.

9. The photovoltaic cell according to claim 1, comprising a semiconductor stack.

10. A photovoltaic string comprising:
a first photovoltaic cell according to claim 1;
a second photovoltaic cell; and
at least one first adhesive portion
said second photovoltaic cell being bonded to the first photovoltaic cell by means of each first adhesive portion, one face of the second photovoltaic cell partially covering the first face of the first photovoltaic cell, each first adhesive portion adhering to a first central free portion of the first face of the first photovoltaic cell and to the face of the second photovoltaic cell.

11. The photovoltaic string according to claim 10, wherein each first adhesive portion is distant from each first interconnection conductor of the first face of the first photovoltaic cell.

12. The photovoltaic string according to claim 10, wherein a plurality of first adhesive portions adhere to the first central free portion of the first face of the first photovoltaic cell and to the face of the second photovoltaic cell.

13. The photovoltaic string according to claim 10, wherein the face of the second photovoltaic cell comprises an edge in vertical alignment with the first face of the first photovoltaic cell, each first adhesive portion being distant from the first edge of the first face of the first photovoltaic cell and from the edge of the face of the second photovoltaic cell.

14. The photovoltaic string according to claim 10, comprising a plurality of second portions of electrically conductive adhesive, each second adhesive portion electrically connecting a first interconnection conductor of the first face of the first photovoltaic cell to the face of the second photovoltaic cell.

15. The photovoltaic string according to claim 14, wherein the length of each first adhesive portion is greater than the length of each second adhesive portion.

16. The photovoltaic string according to claim 14, wherein the width of each first adhesive portion is greater than the width of each second adhesive portion.

17. The photovoltaic string according to claim 14, wherein the face of the second photovoltaic cell comprises a plurality of discrete electrodes spaced apart from each first interconnection conductor of the first face of the first photovoltaic cell, each second adhesive portion connecting a first interconnection conductor to a discrete electrode.

18. The photovoltaic cell according to claim 2, wherein each connection element is disposed as an extension of each first interconnection conductor.

19. The photovoltaic cell according to claim 7, wherein the second distribution track is electrically connected to the first distribution track by a plurality of bonding conductors each extending perpendicular to the first edge, and wherein the width of the second distribution track is equal to the width of the first distribution track.

20. The photovoltaic cell according to claim 9, wherein the semiconductor stack is a heterojunction.
